(19) United States
(12) Patent Application Publication
(10) Pub. No.: US 2010/0121748 A1
(43) Pub. Date: May 13, 2010

(54) Configuring field programmable devices

(75) Inventors: Doran Handelman, Givatayim (IL); Shlomo Kipnis, Jerusalem (IL); Gershon Bar-On, Cochav Hashahar (IL); Daniel Ratner, Haifa (IL)

Correspondence Address: Husch Blackwell Sanders, LLP;Husch Blackwell Sanders LLP Welsh & Katz, 120 S RIVERSIDE PLAZA, 22ND FLOOR, CHICAGO, IL, 60606, US

(73) Assignee: NDS Limited, Staines (GB)

(21) Appl. No.: 12/586,154

(22) Filed: Sep. 16, 2009

Related U.S. Application Data
(63) Continuation of application No. 10/332,868, filed on Jun. 9, 2003.
(60) Provisional application No. 60/275,533, filed on Mar. 12, 2001.

(30) Foreign Application Priority Data
Jul. 13, 2000 (IL) 137296

(51) Int. Cl. G06Q 50/00; G06F 17/50; G06Q 30/00

(52) U.S. Cl. 705/34; 716/11; 716/5

(57) ABSTRACT

A method for reconfiguring a circuit configuration of a configurable hardware device via a communication network. The method includes transmitting via the communication network from a hardware configuration provider unit to the configurable hardware device a circuit reconfiguration of the configurable hardware device in response to a request from a user of the configurable hardware device to reconfigure the configurable hardware device, implementing the circuit reconfiguration of the configurable hardware device thereby reconfiguring the configurable hardware device and providing a reconfigured hardware device and billing the user in response to a determination of correct operation of the reconfigured hardware device. A user unit in a communication network is also disclosed.

### FIELD OF THE INVENTION

The present invention relates to configurable hardware devices, and more particularly to use of configurable hardware devices in consumer appliances.

### BACKGROUND OF THE INVENTION

Today, applications provided by consumer appliances, such as set-top boxes (STBs) and cellular telephones, are typically unchangeable and a user who wants to add or change applications in a consumer appliance needs to purchase additional hardware and to install it in his appliance. Furthermore, broadcasters and communications service providers that are interested in adding capabilities to consumer appliances that they serve must replace or upgrade the consumer appliances and such replacement or upgrading operations are typically time consuming and expensive.

The replacement or upgrading of the consumer appliances may be avoided if the consumer appliances can be upgraded at consumer sites, preferably, from a remote site. This may be achieved by using configurable hardware devices such as Complex Programmable Logic Devices (CPLDs) or Field Programmable Gate Arrays (FPGAs) in the consumer appliances. In a typical upgrading operation, a hardware configuration of a CPLD or an FPGA may be downloaded via the Internet as described in the following publications:

an article published in Hebrew and entitled (in translation) “Working Close, Programming Far”, by Azi Mehtinger in Electronica magazine, Issue 80, September-October 1999, pp. 32-35; and

an article published in Hebrew and entitled (in translation) “Programmable Components and the Internet”, by Azi Mehtinger in Electronica magazine, Issue 77, June-July 1999, pp. 52-53.

Configurable hardware devices are well known in the art and are used in various applications. For example, use of an FPGA instead of an ASIC (Application Specific Integrated Circuit) is discussed in an Internet publication of the ECN Magazine at www.ecmmag.com entitled “Universal Programmers for Production Programming”, dated 1996, and in an article entitled “FPGA High-Level Design Methodology Comes Into Its Own”, by Dave Kresta and Tony Johnson in Electronic Design magazine, Jun. 14, 1999, pp. 57-60.

A family of 3-Volt FPGAs for use in battery-operated portable applications is described in an Internet publication of the ECN Magazine entitled “Family of 3-V Coprocessor FPGAs Designed for Implementing Low-Power, Space-Critical Functions in Battery-Operated, Portable Applications”, dated 1996.

Digital signal processing (DSP) applications of FPGAs and CPLDs are described in the following publications:

a publication entitled “Replace DSPs With FPGAs and CPLDs”, by Alan (“Pete”) Conrad in Microwave & RF magazine, December 1998, pp. 208-211;

an Internet publication of the ECN Magazine entitled “Evolution Dramatically Reduces DSP to FPGA Design Time”, dated 1997; and

an article entitled “FPGA Family Takes on Speed-Critical DSP Applications”, by Dave Bursky in Electronic Design magazine, Feb. 7, 2000, pp. 48.

Applications of programmable processors in set-top boxes (STBs) are described in an article entitled “Set-Top Boxes Flex Their Muscles With Programmable Processors”, by Dave Bursky in Electronic Design magazine, Vol. 47, No. 8, dated Apr. 19, 1999 at www.elecdesign.com.

Some aspects related to technologies of FPGA and CPLD are described in the following articles:

an article entitled “High-Density PLD Family Combines. Best Of FPGAs And CPLDs”, by Dave Bursky in Electronic Design magazine, May 17, 1999, pp. 38-44;

an article entitled “Speedy Flash-Based FPGAs Score With 500-kgate Density”, by Dave Bursky in Electronic Design magazine, Jun. 28, 1999, pp. 35-40; and

an article published in Hebrew and entitled (in translation) “Advanced Integrative Qualities in PLD”, provided by courtesy of Eastronics Company in Electronica magazine, Issue 81, October-November 1999, pp. 104-109.

Some aspects of technologies related to configurable applications in smart cards and other devices are described in the following patents and published patent applications: U.S. Pat. No. 5,721,781; EP 0858644; WO 9825239; WO 9837526; WO 9802834; WO 9830958; WO 9852162; WO 9852161; U.S. Pat. No. 5,689,430; U.S. Pat. No. 5,737,582; U.S. Pat. No. 5,754,762; U.S. Pat. No. 5,624,316; U.S. Pat. No. 5,635,703; U.S. Pat. No. 5,568,179; U.S. Pat. No. 5,530,232; WO 9852152; and WO 9852153.

U.S. Pat. No. 5,774,546 to Handelman et al describes a data access system including a processor, an IC card reader and writer coupled to a processor and including an IC card receptacle, and an IC card that is insertable into the IC card receptacle. The IC card has two separate integrated circuits embodied within, and each of the separate integrated circuits is separately accessible by the IC card reader and writer.

Unpublished Israel patent application 129,230 to Sered et al filed Mar. 29, 1999 and unpublished corresponding PCT patent application PCT/IL00/00103 filed Feb. 20, 2000 describe a method and system for determining that all of a scrambled message, which is typically but not necessarily divided into sub-messages, has been successfully received at a receiver.

The disclosures of all references mentioned above and throughout the present specification are hereby incorporated herein by reference.

### SUMMARY OF THE INVENTION

The present invention seeks to provide an improved method and apparatus for remote configuration of configurable hardware devices at consumer premises via communication networks.

In the present invention, a user of a user unit may transmit via a communication network to a hardware configuration provider a request to reconfigure a configurable hardware device in the user unit. In response to the request of the user, the hardware configuration provider preferably transmits via the communication network a circuit reconfiguration of the configurable hardware device.

The circuit reconfiguration is preferably received at the user unit and implemented in the configurable hardware device thereby generating a reconfigured hardware device. Then, upon determination of correct operation of the reconfigured hardware device, which may be provided by testing the reconfigured hardware device, the user may be billed for the transmitted circuit reconfiguration. Preferably, the following operations are performed without user intervention: implementing the circuit reconfiguration in the configurable hardware device; testing of the to reconfigured hardware device; and billing of the user.

The user unit may include a smart card that provides access control to the circuit reconfiguration and the configurable hardware device. The circuit reconfiguration may include using one of the following: an initial circuit configuration of the configurable hardware device; and a circuit configuration replacing an existing circuit configuration of the configurable hardware device.

The configurable hardware device may include at least one of the following types: an FPGA; and a CPLD. For each type of configurable hardware device, the circuit reconfiguration may include at least one of the following circuit configurations: a digital signal processing (DSP) accelerator; a DES/AES (DES—Data Encryption Standard, AES—Advanced Encryption Standard) supporter; a camera effects controller; a circuit configuration designed to support an operating system (OS); a graphic accelerator; and a modular arithmetic accelerator.

The present invention is applicable for at least the following types of user units: a smart card; a set-top box (STB); a plug-in card for a computer; a micro/nano-robotic device; a television including STB functionality; and a cellular telephone.

There is thus provided in accordance with a preferred embodiment of the present invention a method for reconfiguring a circuit configuration of a configurable hardware device via a communication network, the method including the steps of transmitting via the communication network from a hardware configuration provider unit to the configurable hardware device a circuit reconfiguration of the configurable hardware device in response to a request from a user of the configurable hardware device to reconfigure the configurable hardware device, implementing the circuit reconfiguration of the configurable hardware device thereby reconfiguring the configurable hardware device and providing a reconfigured hardware device, and billing the user in response to a determination of correct operation of the reconfigured hardware device.

Preferably, the configurable hardware device is included in a user unit.

The method also preferably includes the step of testing the reconfigured hardware device to determine correct operation of the reconfigured hardware device after the implementing step. The testing step preferably includes the step of testing the reconfigured hardware device via the hardware configuration provider unit to determine correct operation of the reconfigured hardware device. Preferably, the testing step is performed without user intervention.

The implementing step preferably includes the step of implementing the reconfiguration in the configurable hardware device without user intervention. The billing step preferably includes the steps of generating, at the user unit, a message indicating correct operation of the reconfigured hardware device in response to the determination of correct operation of the reconfigured hardware device, transmitting the message from the user unit to the hardware configuration provider unit, and billing the user in response to reception of the message at the hardware configuration provider unit. The transmitting step preferably includes the step of transmitting the message without user intervention.

Alternatively, the billing step includes the steps of generating, at the hardware configuration provider unit, a message indicating correct operation of the reconfigured hardware device in response to the determination of correct operation of the reconfigured hardware device, and billing the user in response to the message.

Preferably, the request from the user is associated with an indication of agreement of the user to pay for the circuit reconfiguration of the configurable hardware device. The indication of agreement of the user to pay for the circuit reconfiguration of the configurable hardware device preferably includes a representation of financial transaction details and/or a payment identification code.

Alternatively or additionally, the circuit reconfiguration may be associated with an application, and the request from the user may include a payment identification code indicating agreement of the user to pay for the application and for the circuit reconfiguration associated with the application.

Preferably, the method also includes the step of enabling use of the circuit reconfiguration in execution of an application in response to the billing step.

The billing step preferably includes the step of conditionally accessing the circuit reconfiguration to allow use of the circuit reconfiguration in execution of an application. The conditionally accessing step preferably includes the step of generating an enabling key to allow access to the circuit reconfiguration.

Preferably, the circuit reconfiguration of the configurable hardware device is included in an applet including an application program and a circuit reconfiguration file, and the implementing step preferably includes the steps of using the circuit reconfiguration file to implement the circuit reconfiguration so as to provide the reconfigured circuit device, and executing the application program by the reconfigured hardware device.

The applet is preferably signed with a digital signature. The applet may also be encrypted, and the method may also include the step of decrypting the applet prior to the executing step.

Alternatively, the circuit reconfiguration of the configurable hardware device may include a first applet including an application program and a second applet including a circuit reconfiguration file, and the step of transmitting the circuit reconfiguration in response to the request from the user may include the step of transmitting the first applet and the second applet separately. The first applet and the second applet are preferably separately encrypted.

The implementing step may alternatively include the steps of implementing the circuit reconfiguration of the configurable hardware device in the configurable hardware device for a predetermined time period, and deleting the circuit reconfiguration of the configurable hardware device from the configurable hardware device after the predetermined time period elapses. The deleting step preferably includes the steps of transmitting a delete signal from the hardware configuration provider unit to the configurable hardware device when the predetermined time period elapses, and erasing the circuit reconfiguration from the configurable hardware device in response to the delete signal.

There is also provided in accordance with a preferred embodiment of the present invention a method for reconfiguring a circuit configuration of a configurable hardware device with a circuit reconfiguration which is operative to execute an application in a first communication network, the method including the steps of transmitting the circuit reconfiguration via a second communication network from a hardware configuration provider unit to the configurable hardware device, implementing the circuit reconfiguration in the configurable hardware device thereby proving a reconfigured hardware device, and employing the reconfigured hardware device reconfigured by the circuit reconfiguration to execute the application in the first communication network.

Further in accordance with a preferred embodiment of the present invention there is provided a method for reconfiguring a circuit configuration of a configurable hardware device with a circuit reconfiguration, the method including the steps of transmitting a first portion of the circuit reconfiguration via a first communication network from a hardware configuration provider unit to the configurable hardware device, implementing the first portion of the circuit reconfiguration in the configurable hardware device thereby providing a partially reconfigured hardware device, transmitting a second portion of the circuit reconfiguration via a second communication network from the hardware configuration provider unit to the configurable hardware device, the entire circuit configuration including the second portion of the circuit reconfiguration and the first portion of the circuit reconfiguration, implementing the second portion of the circuit reconfiguration in the configurable hardware device thereby providing an entirely reconfigured hardware device, and employing the entirely reconfigured hardware device to execute an application in one of the following: the first communication network, and the second communication network.

Still further in accordance with a preferred embodiment of the present invention there is provided a method for reconfiguring a circuit configuration of a configurable hardware device with a circuit reconfiguration enabling performance of a complex mathematical computation, the method including the steps of transmitting a first portion of the circuit reconfiguration via a communication network from a hardware configuration provider unit to the configurable hardware device, the first portion of the circuit reconfiguration being useful for performing a first set of mathematical computations from the complex mathematical computation, implementing the first portion of the circuit reconfiguration in the configurable hardware device thereby providing a partially reconfigured hardware device, operating the partially reconfigured hardware device to perform the first set of mathematical computations, transmitting a second portion of the circuit reconfiguration via a communication network from the hardware configuration provider unit to the configurable hardware device, the second portion of the circuit reconfiguration being useful for performing a second set of mathematical computations from the complex mathematical computation, wherein the complex mathematical computation includes the first set of mathematical computations and the second set of mathematical computations, implementing the second portion of the circuit reconfiguration in the configurable hardware device thereby providing an entirely reconfigured hardware device, and operating the entirely reconfigured hardware device to perform the second set of mathematical computations thereby completing the complex mathematical computation.

There is also provided in accordance with a preferred embodiment of the present invention a user unit in a communication network, the user unit including a configurable hardware device, and a communication interface unit operatively associated with the communication network and the configurable hardware device and operative to receive, from a hardware configuration provider unit via the communication network, a circuit reconfiguration of the configurable hardware device in response to a request from a user of the user unit to reconfigure the configurable hardware device in the user unit, wherein the user is billed when both of the following have occurred: implementation of the circuit reconfiguration in the configurable hardware device so as to provide a reconfigured hardware device, and determination of correct operation of the reconfigured hardware device.

Additionally, the user unit also includes an appliance operatively associated with the configurable hardware device, wherein the configurable hardware device, when configured by the circuit reconfiguration, is operative to change behavior of the appliance. The appliance may include a smart card or one of the following: a set-top box (STB), a plug-in card for a computer, a micro/nano-robotic device, a television including STB functionality, and a cellular telephone.

Preferably, the circuit reconfiguration of the configurable hardware device includes one of the following: an initial circuit configuration of the configurable hardware device, and a circuit configuration replacing an existing circuit configuration of the configurable hardware device. Additionally, the circuit reconfiguration may include at least one of the following circuit configurations: a digital signal processing (DSP) accelerator, a DES/AES supporter, a camera effects controller, a circuit configuration designed to support an operating system (OS), a graphic accelerator, and a modular arithmetic accelerator.

The configurable hardware device preferably includes at least one of the following: an FPGA, and a CPLD. The hardware configuration provider unit is preferably included in a headend of a pay television network, and the communication network preferably includes a pay television network.

Additionally, the user unit also includes a processor operatively associated with the configurable hardware device and the communication interface unit, and the processor is operative to enable billing of the user when both of the following have occurred: the implementation of the circuit reconfiguration in the configurable hardware device so as to provide a reconfigured hardware device, and the determination of correct operation of the reconfigured hardware device.

Preferably, the processor is also operative to test the reconfigured hardware device so as to provide the determination of correct operation of the reconfigured hardware device.

The user unit may additionally include a security element operatively associated with the configurable hardware device and operative to provide conditional access to the circuit reconfiguration by conditionally allowing use of the circuit reconfiguration in execution of an application. The security element preferably includes a removable security element. The removable security element preferably includes a smart card.

Preferably, the communication interface unit is also operatively associated with an additional communication network, and the reconfigured hardware device is employed to execute an application in the additional communication network.

The circuit reconfiguration may be implemented for a predetermined time period predetermined by the processor, and the processor may be operative to generate a command for deleting the circuit reconfiguration after the predetermined time period elapses. Alternatively, the predetermined time period may be predetermined by the hardware configuration provider unit, and the hardware configuration provider unit may be operative to generate a command for deleting the circuit reconfiguration after the predetermined time period elapses.

The user unit may also preferably include a server operative to serve a plurality of appliances. In such a case, the circuit reconfiguration may include a plurality of sub-circuit reconfigurations, and each sub-circuit reconfiguration is operative to execute an application associated with one of the plurality of appliances.

Alternatively, the circuit reconfiguration may be used in a time-sharing basis to execute applications associated with the plurality of appliances.

Further in accordance with a preferred embodiment of the present invention there is provided a user unit in a first communication network, the user unit including a configurable hardware device, and a communication interface unit operatively associated with the first communication network, a second communication network and the configurable hardware device and operative to receive a first portion of a circuit reconfiguration of the configurable hardware device from a first hardware configuration provider unit via the first communication network, and a second portion of the circuit reconfiguration of the configurable hardware device from a second hardware configuration provider unit via the second communication network, the entire circuit reconfiguration including the second portion of the circuit reconfiguration and the first portion of the circuit reconfiguration, wherein after implementation of the entire circuit reconfiguration in the configurable hardware device so as to provide an entirely reconfigured hardware device, the entirely reconfigured hardware device is operative to execute an application in one of the following: the first communication network, and the second communication network.

Still further in accordance with a preferred embodiment of the present invention there is provided a user unit in a communication network, the user unit including a configurable hardware device, and a communication interface unit operatively associated with the communication network and the configurable hardware device and operative to separately receive a first portion of a circuit reconfiguration of the configurable hardware device and a second portion of the circuit reconfiguration of the configurable hardware device from a hardware configuration provider unit via the communication network, the first portion of the circuit reconfiguration being useful for performing a first set of mathematical computations included in a complex mathematical computation, the second portion of the circuit reconfiguration being useful for performing a second set of mathematical computations included in the complex mathematical computation, wherein after implementation of the first portion of the circuit reconfiguration in the configurable hardware device, the configurable hardware device is enabled to perform the first set of mathematical computations, and after the implementation of the first portion and after implementation of the second portion of the circuit reconfiguration in the configurable hardware device, the configurable hardware device is enabled to complete the complex mathematical computation.

There is also provided in accordance with a preferred embodiment of the present invention a communication system including a communication network, a hardware configuration provider unit operatively associated with the communication network, and a multiplicity of user units operatively associated with the hardware configuration provider unit, each of the multiplicity of user units including a configurable hardware device, and a communication interface unit operatively associated with the communication network and the configurable hardware device and operative to receive, from the hardware configuration provider unit via the communication network, a circuit reconfiguration of the configurable hardware device, wherein upon implementation of the circuit reconfiguration in the configurable hardware device so as to provide a reconfigured hardware device and determination of correct operation of the reconfigured hardware device, billing for the circuit reconfiguration is enabled.

### BRIEF DESCRIPTION OF TEE DRAWINGS

The present invention will be understood and appreciated more fully from the following detailed description, taken in conjunction with the drawings in which:

FIG. 1 is a simplified partly pictorial, partly block diagram illustration of a communication system constructed and operative in accordance with a preferred embodiment of the present invention;

FIG. 2 is a simplified partly pictorial, partly block diagram illustration of a preferred embodiment of a user unit in the communication system of FIG. 1;

FIG. 3 is a simplified block diagram illustration of a preferred implementation of a circuit reconfiguration of a configurable hardware device in the user unit of FIG. 2;

FIGS. 4A and 4B are simplified partly pictorial, partly block diagram illustrations of preferred implementations of smart cards in the user unit of FIG. 2;

FIG. 5 is a simplified partly pictorial, partly block diagram illustration of a preferred implementation of an appliance including the user unit of FIG. 2; and

FIG. 6 is a simplified flowchart illustration of a preferred method of operation of the apparatus of FIGS. 1 and 2.

### DETAILED DESCRIPTION OF A PREFERRED EMBODIMENT

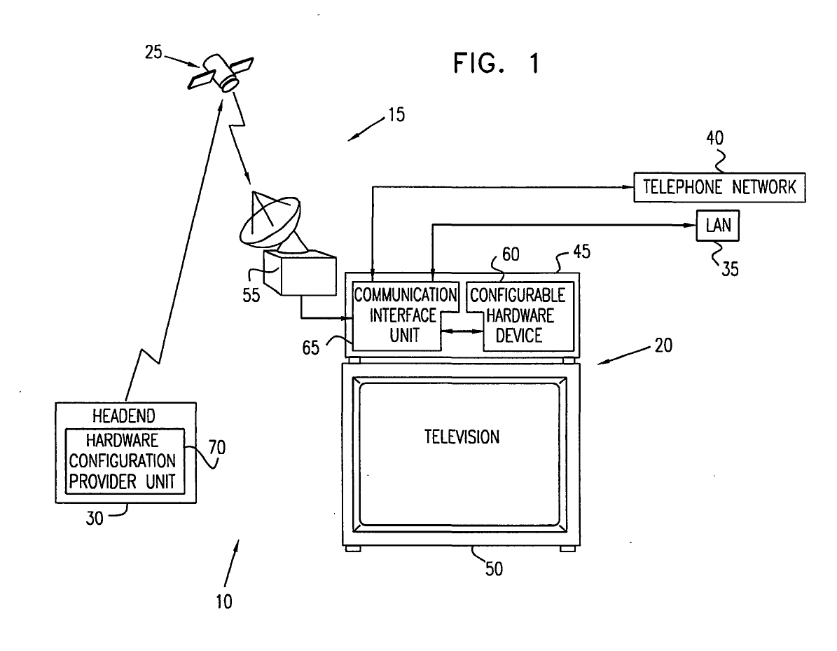

Reference is now made to FIG. 1 which is a simplified partly pictorial, partly block diagram illustration of a communication system constructed and operative in accordance with a preferred embodiment of the present invention.

The communication system 10 preferably includes a communication network 15. The communication network 15 may preferably include at least one of the following: a broadcast or a multicast network; a unicast network; and a telephone network. It is appreciated that the present invention is not limited by the type of communication network 15 used in the communication system 10 and/or by the type of communicating termini in the communication system 10.

In a case where the communication network 15 includes a broadcast or a multicast network, the broadcast or multicast network may be a one-way or a two-way network and may include a television network or a multicast computer network. In a case where the communication network 15 includes a unicast network, the unicast network may include a one-way or a two-way unicast computer network. Both the multicast computer network and the unicast computer network may be implemented by at least one of the following: a local-area-network (LAN); a metropolitan-area-network (MAN); and a wide-area-network (WAN).

The television network may be implemented via infrastructure including any combination of coaxial cables, satellite, telephone wires, and fiber optic cables. It is appreciated that the television network may include a pay television network.

In a case where the communication network 15 includes a telephone network, the telephone network may include a cellular telephone network or a wired telephone network that may be implemented via infrastructure including, for example, any combination of coaxial cables, satellite, telephone wires, and fiber optic cables.

The communication system 10 preferably enables communication between two ends of the communication system 10 via the communication network 15. By way of example, the communication network 15 in FIG. 1 is a television network and a user unit 20 may communicate via a satellite 25 with a headend 30 of the television network 15. Additionally or alternatively, the user unit 20 may communicate with a local-area-network (LAN) 35 and a telephone network 40. However, it is appreciated that the user unit 20 may communicate with any number of networks via suitable interfaces. The user unit 20 is preferably one of a multiplicity of user units that may communicate with each of the television network 15, the LAN 35 and the telephone network 40.

The user unit 20 preferably includes an appliance, such as a set-top box (STB) 45 that may be associated with a television 50. Alternatively, the STB 45 and the television 50 may be replaced by a television including STB functionality (not shown). The STB 45 is preferably associated with an antenna 55 for reception of transmissions from the headend 30.

The appliance included in the user unit 20 may alternatively include one of the following: a plug-in card for a computer; a micro/nano-robotic device; and a cellular telephone. In such a case, the television 50 may be replaced, for to example, by a built-in display (not shown) in the appliance.

Referring, for example, to a case in which the user unit 20 includes the STB 45 and the television 50, the STB 45 may preferably include a configurable hardware device 60 and a communication interface unit 65 operatively associated with the configurable hardware device 60. The communication interface unit 65 is also preferably operatively associated with the communication network 15 and is operative to receive, from a hardware configuration provider unit 70 via the communication network 15, a circuit reconfiguration of the configurable hardware device 60. Preferably, the hardware configuration provider unit 70 may be located at one of the following locations: the headend 30; a telephone node (not shown); and a LAN node (not shown).

It is appreciated that the circuit reconfiguration of the configurable hardware device may be received in response to a request from a user of the user unit 20 to reconfigure the configurable hardware device 60 in the user unit 20. Preferably, upon implementation of the circuit reconfiguration in the configurable hardware device 60 so as to provide a reconfigured hardware device 60, and upon determination of correct operation of the reconfigured hardware device 60, the user of the user unit 20 may be billed.

Preferably, the configurable hardware device 60 implements the circuit reconfiguration without user intervention. It is appreciated that the configurable hardware device 60 may operate either in a non-volatile mode in which the circuit reconfiguration is maintained when the STB 45 is turned off, or in a volatile mode in which the circuit configuration is erased when the STB 45 is turned off. Preferably, a price for the circuit reconfiguration may differ according to the mode in which the configurable hardware device 60 operates.

The circuit reconfiguration is preferably intended to change behavior of the STB 45, such as by changing an algorithm performed by the STB 45, by changing an operation mode of the STB 45 and so forth. It is appreciated that by changing the behavior of the STB 45, performance of the STB 45 may change, and therefore, upon operation of the reconfigured hardware device 60, the performance of the STB 45 may be changed and typically enhanced with respect to performance of the STB 45 before implementation of the circuit reconfiguration.

Preferably, circuit reconfiguration of the configurable hardware device 60 may include one of the following circuit configurations: an initial circuit configuration of the configurable hardware device 60; and a circuit configuration replacing an existing circuit configuration of the configurable hardware device 60.

The configurable hardware device 60 may preferably include, for example, at least one of the following: an FPGA (Field Programmable Gate Array); and a CPLD (Complex Programmable Logic Device). The circuit reconfiguration, for each type of the configurable hardware device 60 being used in the user unit 20, may preferably include, for example, at least one of the following circuit configurations: a digital signal processing (DSP) accelerator; a DES (Data Encryption Standard) or AES (Advanced Encryption Standard) supporter; a camera effects controller; a circuit configuration designed to support an operating system (OS); a graphic accelerator; and a modular arithmetic accelerator.

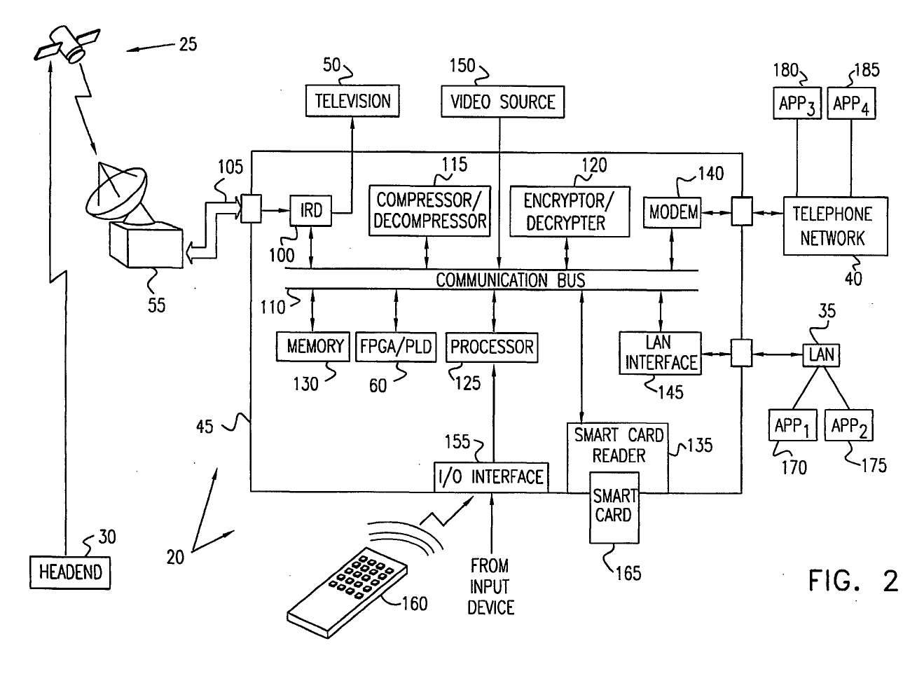

Reference is now additionally made to FIG. 2 which is a simplified partly pictorial, partly block diagram illustration of a preferred embodiment of a user unit in the communication system of FIG. 1.

Referring, for example, to a case in which transmissions from the headend 30 to the user unit 20 include television transmissions and the user unit 20 includes the STB 45, the television transmissions received at the antenna 55 may preferably include conventional television programs as well as pay television transmissions and data in television format. The data in television format may include; for example, multimedia data, computer-generated data and applications, world-wide-web (web) pages, teletext, video games, computer program codes, and audio data.

The antenna 55 that receives the television transmissions preferably provides the television transmissions to an integrated receiver and decoder (IRD) 100 in the STB 45 via cables 105, such as coaxial cables. It is appreciated that the antenna 55 may be a receive/transmit antenna that may also transmit information provided via the IRD 100. In such a case, the antenna 55 may be part of a conventional VSAT (Very Small Aperture Terminal) (not shown).

Preferably, the IRD 100 is operative to receive and decode the television transmissions and to provide decoded television transmissions to the television 50. It is appreciated that the television transmissions may be provided either in an analog format or in a digital format, and accordingly the IRD 100 may be either an analog IRD or a digital IRD.

The IRD 100 is preferably operatively associated with a communication bus 110 in the STB 45. The following units may be embodied in the STB 45 and also preferably operatively associated with the communication bus 110: a compressor/decompressor 115; an encryptor/decrypter 120; a processor 125; a memory 130; a security element reader, such as smart card reader 135; a telephone modem 140; the configurable hardware device 60; and a LAN interface 145. Alternatively, the compressor/decompressor 115, the encryptor/decrypter 120, the processor 125, the memory 130, the security element reader 135, the modem 140, the configurable hardware device 60, and the LAN interface 145 may be operative to communicate with each other directly without using bus communication.

Preferably, the LAN interface 145 may be employed to communicate in two-way communication with the LAN 35. The telephone modem 140 may be employed to communicate, for example, with the Internet, via the telephone network 40. Alternatively or additionally, television transmissions may be provided to the user unit 20 via telephone, and Internet transmissions may be provided via the headend 30 and the satellite 25. The user unit 20 may also receive video transmissions from an external video source 150.

Thus, it is appreciated that the user unit 20 may receive information in various forms from a variety of sources and via networks comprised in the communication network 15. The information provided to the user unit 20 may preferably be received via at least one of the following: the IRD 100; the modem 140; and the LAN interface 145. It is further appreciated that at least one of the following: the IRD 100; the modem 140; and the LAN interface 145 may be included in the communication interface unit 65.

The processor 125 is preferably operatively associated with an input/output (I/O) interface 155 which is operative to receive inputs from at least one input device, such as a remote control 160, a keyboard (not shown), and a mouse (not shown). Preferably, the processor 125 may use inputs received via the I/O interface 155 to browse through or make selections from the information received via the communication network 15.

The security element reader 135 is preferably operative to accept a security element that may preferably include a removable security element such as a smart card 165. Preferably, the security element reader 135 is operative to read data from and to write data into the smart card 165. The smart card 165 is preferably operatively associated with the configurable hardware device 60 via the communication bus 110 and is preferably operative to provide conditional access to the configurable hardware device 60 by conditionally allowing at least one of the following: loading a circuit reconfiguration into the configurable hardware device 60; and using the circuit reconfiguration in execution of an application by the configurable hardware device 60.

It is appreciated that the processor 125 may be embodied in the smart card 165 or in any other removable element (not shown). In such a case, the smart card 165, or the removable element, may be operative to perform all the functions of the processor 125, and the processor 125 may be optional. The configurable hardware device 60 may also be embodied in a removable element (not shown) which may be accessed by an external card reader (not shown) that is operatively associated with the communication bus 110.

The memory 130 may preferably be used to store information for use by the processor 125. It is appreciated that the memory 130 may be either an internal memory, or may be embodied in the smart card 165 or in a removable memory card (not shown) accessed by a memory reader (not shown).

The compressor/decompressor 115 may preferably be used to compress information before transmission from the user unit 20 and to decompress compressed information received at the user unit 20. The encryptor/decrypter 120 may preferably be used to encrypt information before transmission from the user unit 20 and to decrypt encrypted information received at the user unit 20. Alternatively, a separate encryptor and a separate decrypter (not shown) may be provided, or only one of an encryptor and a decrypter may be provided. The compressor/decompressor 115 and the encryptor/decrypter 120 may each operate in a conventional manner, as is well known in the art, and may preferably be implemented in any appropriate combination of hardware and software such as, for example, in the processor 125.

It is appreciated that the information encrypted/decrypted by the encryptor/decrypter 120 may include various types of information such as computer data, television transmissions, and applets such as applets that include circuit reconfigurations of the configurable hardware device 60 as described below. Similarly, the information compressed/decompressed by the compressor/decompressor 115 may include various types of information such as computer data, television transmissions, and applets such as applets that include circuit reconfigurations of the configurable hardware device 60 as described below.

It is appreciated that the user unit 20, due to its network connectivity, may also function as a server for serving a plurality of appliances, such as appliances 170, 175, 180 and 185, by providing, for example, updates of operational data to the appliances 170, 175, 180 and 185. The updates of operational data may be used, for example, to expand the variety of features supported by the plurality of appliances and to enable the plurality of appliances to use software updates and a variety of software programs. It is appreciated that the user unit 20 may be operative to serve the plurality of appliances via at least one of the following: the modem 140; the LAN interface 145; and the IRD 100. In the example depicted in FIG. 2, the user unit 20 serves the appliances 170 and 175 via the LAN interface 145 and the LAN 30, and the appliances 180 and 185 via the modem 140 and the telephone network 40. It is appreciated that the number of appliances served by the user unit 20 may vary.

The operation of the apparatus of FIGS. 1 and 2 is now briefly described. A user of the user unit 20 may transmit to an operator of the hardware configuration provider unit 70, typically located at premises of a hardware configuration provider (not shown), a request to upgrade the user unit 20 or to change the functionality of the user unit 20. Such an upgrade or functionality change may be required in order to enable execution of applications that require, for example, rich-graphics, camera effects, DSP acceleration, various kinds of encryption/decryption algorithms or methods, and so forth.

The upgrade or the functionality change may be provided by reconfiguring the configurable hardware device 60 in the user unit 20 with a circuit reconfiguration having an enhanced required processing ability. The term “reconfiguration” in all of its forms is used throughout the specification and claims to include use of an initial configuration as well as a configuration replacing an existing configuration. Thus, the circuit reconfiguration of the configurable hardware device 60 in the user unit 20 may include use of one of the following: an initial circuit configuration of the configurable hardware device 60; and a circuit configuration replacing an existing circuit configuration of the configurable hardware device 60.

The enhanced required processing ability may be provided, for example, by a circuit reconfiguration having a digital signal processing (DSP) accelerator that enhances processing of applications that require DSP. Applications that require encryption/decryption processing may be enhanced, for example, by a circuit configuration having a DES/AES support subsystem. Other examples of circuit configurations that may enhance processing of applications may include the following: a camera effects controller; a circuit configuration designed to support an operating system (OS); a graphic accelerator; and a modular arithmetic accelerator.

Preferably, the request from the user may be associated with an indication of agreement of the user to pay for the circuit reconfiguration of the configurable hardware device 60. It is appreciated that the indication of agreement of the user to pay for the circuit reconfiguration of the configurable hardware device 60 may include a representation of financial transaction details and/or a payment identification code that may be processed to enable billing of the user. Alternatively or additionally, the circuit reconfiguration may be associated with an application, and the request from the user may include a payment identification code indicating agreement of the user to pay for both the application and the circuit reconfiguration associated with the application.

In the case where the hardware configuration provider unit 70 is located at the headend 30, transmission of the request to the hardware configuration provider may preferably include transmission, by the processor 125, of the payment identification code in the upstream to the headend 30 via one of the IRD 100, the modem 140 and the LAN interface 145. The headend 30 may then process the payment identification code to bill the user or send an indication of the request of the user together with billing information obtained from the payment identification code to the hardware configuration provider thereby enabling the hardware configuration provider to bill the user.

The term “upstream” is used throughout the specification and claims to refer to a direction of communication from the user unit 20 to the headend 30 or the hardware configuration provider, and the term “downstream” is used to refer to a direction of communication from the hardware configuration provider or the headend 30 to the user unit 20.

Preferably, in response to the request of the user of the user unit 20 to reconfigure the configurable hardware device 60 in the user unit 20, the hardware configuration provider may use the hardware configuration provider unit 70 to transmit to the user unit 20, in the downstream via the communication network 15, a circuit reconfiguration of the configurable hardware device 60 in the user unit 20. It is appreciated that the circuit reconfiguration transmitted to the user unit 20 may be signed by a digital signature prior to transmission thereof.

At the user unit 20, the smart card 165 or the processor 125 may perform an authentication procedure to verify authenticity of the signature associated with the circuit reconfiguration transmitted by the hardware configuration provider. If authenticity of the signature is verified, the circuit reconfiguration may be received and implemented at the user unit 20. It is appreciated that the circuit reconfiguration may be received via the communication network 15 at one of the IRD 100, the modem 140 and the LAN interface 145 depending on a communication path used to transmit the circuit reconfiguration.

The circuit reconfiguration may however be transmitted over more than one communication path so that, for example, a first portion of the circuit to reconfiguration may be transmitted from the hardware configuration provider unit 70 via the LAN 35, and a second portion of the circuit reconfiguration may be broadcast from the hardware configuration provider unit 70 via the satellite 25. It is appreciated that the first portion of the circuit reconfiguration together with the second portion of the circuit reconfiguration form the entire circuit reconfiguration.

Once the circuit reconfiguration is entirely received at the user unit 20, the configurable hardware device 60 preferably implements the circuit reconfiguration in the configurable hardware device 60 in the user unit 20, thereby reconfiguring the configurable hardware device 60 and providing a reconfigured hardware device 60. Preferably, implementation of the circuit reconfiguration in the configurable hardware device 60 in the user unit 20 may be performed without user intervention.

It is appreciated that implementation of the circuit reconfiguration in the configurable hardware device 60 may be controlled by the processor 125 or the smart card 165. The smart card 165 may also provide conditional access to allow the implementation of the circuit reconfiguration in the configurable hardware device 60 only under certain conditions, such as only when there was prior registration in a database (not shown) supported by the hardware configuration provider.

In the case where the circuit reconfiguration is transmitted over more than one communication path, the circuit reconfiguration may be implemented in more than one stage. In a first stage, the first portion of the circuit reconfiguration may be implemented so as to provide a partially reconfigured hardware device 60. In a second stage, the second portion of the circuit reconfiguration is implemented thereby completing reconfiguration of the configurable hardware device 60 so as to provide the reconfigured hardware device 60 being entirely reconfigured. In such a case, the processor 125 or the smart card 165 may control implementation of at least one of the following: the first portion of the circuit reconfiguration; the second portion of the circuit reconfiguration; and the entire circuit reconfiguration.

Additionally or alternatively, the smart card 165 may provide conditional access to allow the implementation in the configurable hardware device 60 under certain conditions of at least one of the following: the first portion of the circuit reconfiguration; the second portion of the circuit reconfiguration; and the entire circuit reconfiguration.

Preferably, once the circuit reconfiguration is implemented in the configurable hardware device 60 so as to provide the reconfigured hardware device 60, and upon determination of correct operation of the reconfigured hardware device 60, the user may be billed for the circuit reconfiguration. It is appreciated that the processor 125 may be operative to enable billing of the user. Alternatively or additionally, the processor 125 may be operative to execute billing operations so as to bill the user upon the implementation of the circuit reconfiguration in the configurable hardware device 60 and the determination of correct operation of the reconfigured hardware device 60. Further alternatively, the user may be billed by the hardware configuration provider, for example via the hardware configuration provider unit 70, upon the implementation of the circuit reconfiguration in the configurable hardware device 60 and the determination of correct operation of the reconfigured hardware device 60.

Preferably, in order to determine correct operation of the reconfigured hardware device 60, the reconfigured hardware device 60 may be tested. Testing of the reconfigured hardware device 60 may include, for example, performance of a sample program. If the reconfigured hardware device 60 performs the sample program properly, the reconfigured hardware device 60 is preferably considered to operate correctly and the user may be billed as mentioned above.

Preferably, the testing of the reconfigured hardware device 60 may be performed by the hardware configuration provider or by a testing entity (not shown) via the hardware configuration provider unit 70. Alternatively, the processor 125 or the smart card 165 may be operative to test the reconfigured hardware device 60. Further alternatively, the configurable hardware device 60, upon implementation of the circuit reconfiguration, may be operative to automatically perform a testing program and to output a test result to the hardware configuration provider unit 70 or to the processor 125.

It is appreciated that regardless of the device that tests the reconfigured hardware device 60, the testing of the reconfigured hardware device 60 is preferably performed without user intervention. Alternatively, the testing of the reconfigured hardware device 60 may be performed with user intervention.

Preferably, when the billing of the user is enabled in response to the determination of correct operation of the reconfigured hardware device 60, the processor 125 may preferably generate a message indicating correct operation of the reconfigured hardware device 60. Then, the processor 125 may be operative to transmit the message from the user unit 20 to the hardware configuration provider unit 70 via one of the modem 140, the LAN interface 145, and the MD 100. Preferably, the user may be billed, either at the hardware configuration provider unit 70 or at the user unit 20, in response to reception of the message at the hardware configuration provider unit 70. It is appreciated that the message may be transmitted to the hardware configuration provider unit 70 without user intervention.

If the user is billed at the user unit 20, billing operations are preferably performed in the smart card 165, and the smart card 165 may keep billing records of the user. Alternatively, the processor 125 may perform the billing operations, and the billing records of the user may be kept in the memory 130 or in the smart card 165.

In a case where the billing of the user is performed at the hardware configuration provider unit 70, the hardware configuration provider unit 70, and not the processor 125, may be operative to generate the message indicating correct operation of the reconfigured hardware device 60. In such a case, the hardware configuration provider unit 70 may be operative to perform the billing operations in response to generation of the message.

The billing of the user may preferably be performed in association with a conditional access process in which the circuit reconfiguration is conditionally accessed to allow use of the circuit reconfiguration in execution of any required application or a specific set of applications. Preferably, the conditional access process includes a conventional conditional access process that is performed in the smart card 165. The conditional access process preferably results in generation of an enabling key to allow access to the circuit reconfiguration.

Preferably, upon billing of the user and fulfillment of other conditional access requirements that may exist, the reconfigured hardware device 60 is enabled to execute any required application or the specific set of applications in accordance with terms of purchase of the circuit reconfiguration. The terms of purchase of the circuit reconfiguration may include, for example, the following: use of the circuit reconfiguration to execute applications in only one of the networks that form part of the communication network 15; and use of the circuit reconfiguration to execute applications for a predetermined limited time period after which the circuit reconfiguration is deleted.

Alternatively, the terms of purchase of the circuit reconfiguration may not limit use of the circuit reconfiguration. In such a case the circuit reconfiguration may be used for an unlimited time period for any applications, and also for executing any applications in any of the networks that form part of the communication network 15 regardless of the network via which the circuit configuration was downloaded.

In a case where use of the circuit reconfiguration is limited for a predetermined time period, the hardware configuration provider unit 70 may determine the predetermined time period and transmit a delete signal to the user unit 20 when the predetermined time period elapses. Then, the processor 125 or the configurable hardware device 60 may delete the circuit reconfiguration in response to the delete signal. Alternatively, the processor 125 may determine the predetermined time period and generate a delete command for deleting the circuit reconfiguration when the predetermined time period elapses. Then, the processor 125 or the configurable hardware device 60 may delete the circuit reconfiguration in response to the delete command.

The circuit reconfiguration transmitted from the hardware configuration provider to the user unit 20 is preferably included in an applet. The applet preferably includes an application program and a circuit reconfiguration file. The circuit reconfiguration file is preferably used to reconfigure the configurable hardware device 60 so as to provide the reconfigured hardware device 60. The application program may preferably include a program for execution by the reconfigured hardware device 60.

Alternatively, the application program may be comprised in a first applet, the circuit reconfiguration file may be comprised in a second applet, and the first applet and the second applet may preferably be transmitted to the user unit 20 separately.

Is The applet, or the first and second applets, may preferably be signed with a digital signature by a recognized center (not shown). The applet, or the first and second applets, may also be transmitted in an encrypted form, and the encryptor/decrypter 120 may decrypt the applet, or the first and second applets, prior to implementation of the circuit reconfiguration and execution of the application program. It is appreciated that the first applet and the second applet may be separately encrypted. It is further appreciated that in a case where the applet is signed with a digital signature by the recognized center, the circuit configuration file or the application program need not be signed separately by digital signatures.

In another preferred embodiment of the present invention, when a circuit reconfiguration that enables performance of a complex mathematical computation is transmitted to the user unit 20, the hardware configuration provider 70 may separately transmit, for example, a first portion of the circuit reconfiguration and a second portion of the circuit reconfiguration. The first portion of the circuit reconfiguration is preferably useful for performing a first set of mathematical computations from the complex mathematical computation, such as addition and subtraction. The second portion of the circuit reconfiguration is preferably useful for performing a second set of mathematical computations from the complex mathematical computation, such as multiplication and division. The combination of the first set of mathematical computations and the second set of mathematical computations preferably form the entire complex mathematical computation.

Once the first portion of the circuit reconfiguration is received at the user unit 20, the first portion of the circuit reconfiguration may be implemented in the configurable hardware device 60 thereby providing a partially reconfigured hardware device 60. The partially reconfigured hardware device 60 may be operated to perform only the first set of mathematical computations.

When the second portion of the circuit reconfiguration is received at the user unit 20, the second portion of the circuit reconfiguration may be implemented in the partially reconfigured hardware device 60 thereby providing an entirely reconfigured hardware device 60. The entirely reconfigured hardware device 60 may then be operated to complete performance of the complex mathematical computation by performing the second set of mathematical computations in addition to the first set of mathematical computations previously performed.

The use of separate portions of a circuit reconfiguration to execute separate mathematical computations may be useful when performed frequently, such as within a few minutes, in applications that require large memories that are not available at the user unit 20. In such a case, only results of the separate portions may be stored thereby saving memory space.

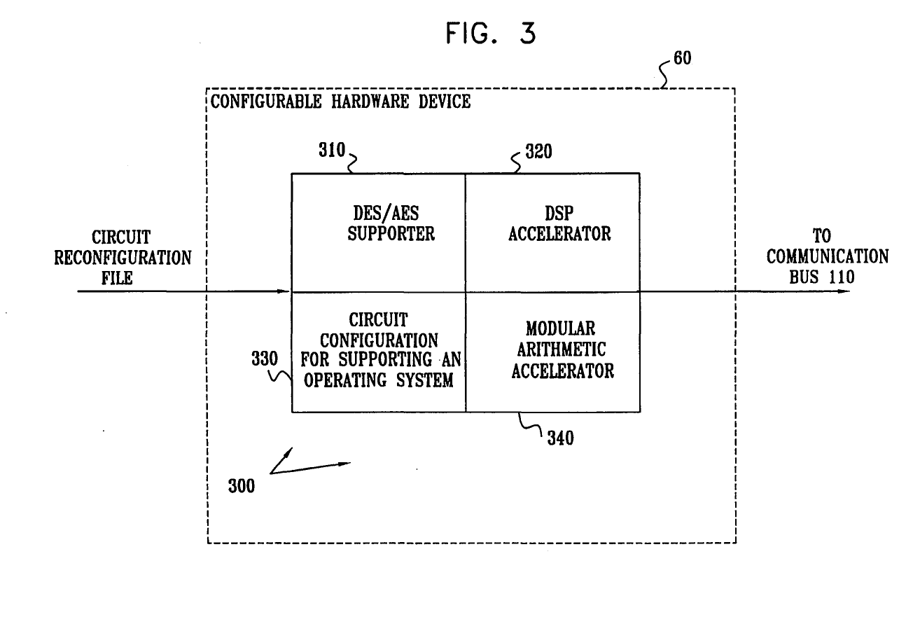

Reference is now additionally made to FIG. 3 which is a simplified block diagram illustration of a preferred implementation of a circuit reconfiguration of a configurable hardware device in the user unit of FIG. 2.

The circuit reconfiguration 300 may preferably be generated by implementation of a circuit reconfiguration file that is included in an applet transmitted by the hardware configuration provider.

The circuit reconfiguration 300 may be useful in the case where the user unit 20 operates as a server serving the appliances 170, 175, 180 and 185 as mentioned above. Preferably, the circuit reconfiguration 300 includes sub-circuit reconfigurations 310, 320, 330 and 340 which may be used with the appliances 170, 175, 180 and 185 respectively.

For example, if the appliance 170 includes a computerized e-commerce device that uses encryption/decryption for performance of various operations related to purchase of items, the sub-circuit reconfiguration 310 may include a DES/AES supporter that may be used by the appliance 170 to perform DES/AES encryption/decryption operations. If, for example, the appliance 175 includes a voice recognition device that uses DSP, the sub-circuit reconfiguration 320 may include, for example, a DSP accelerator that may be used by the appliance 175 to enhance DSP operations. It is appreciated that the appliances 170 and 175 preferably communicate with the configurable hardware device 60 via the LAN 35 in order to respectively use the sub-circuit reconfigurations 310 and 320.

If the appliance 180 includes a computer system, the sub-circuit reconfiguration 330 may include, for example, a circuit configuration designed to support an operating system (OS) that may be used by the appliance 180 to support various types of operating systems. If the appliance 185 includes a computer system that runs applications that use modular arithmetic, the sub-circuit reconfiguration 340 may include, for example, a modular arithmetic accelerator that may be used by the appliance 185 to accelerate performance of the applications that use modular arithmetic. It is appreciated that the appliances 180 and 185 preferably communicate with the configurable hardware device 60 via the telephone network 40 in order to respectively use the sub-circuit reconfigurations 330 and 340.

In another preferred embodiment of the present invention, the circuit reconfiguration 300 may be used on a time-sharing basis to execute applications associated with the appliances 170, 175, 180 and 185 via the networks 35 and 40 respectively. In such a case, each of the appliances 170, 175, 180 and 185 may use each of the sub-circuit reconfigurations 310, 320, 330 and 340 but on a time sharing basis.

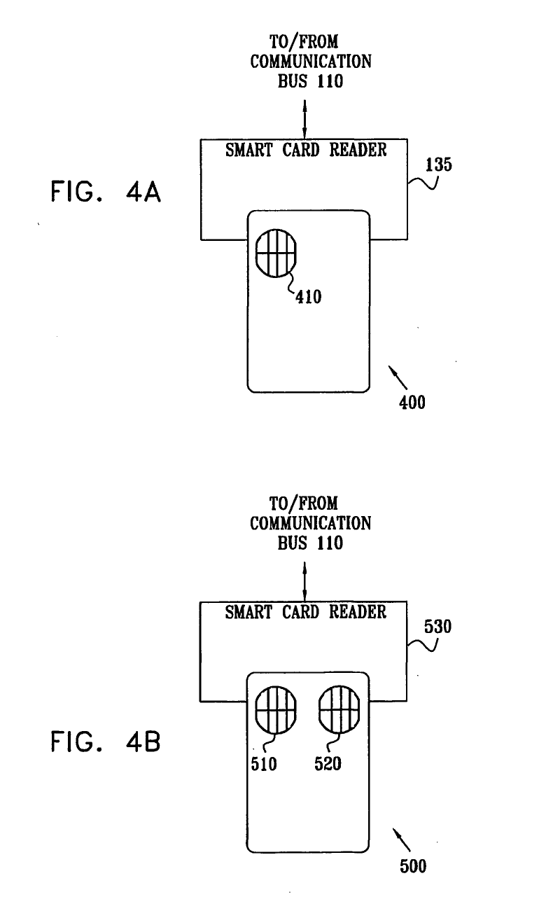

Reference is now additionally made to FIGS. 4A and 4B which are simplified partly pictorial, partly block diagram illustrations of preferred implementations of smart cards in the user unit of FIG. 2.

Smart cards 400 and 500 respectively may each replace both the smart card 165 and the configurable hardware device 60 in the user unit 20 of FIG. 2.

Preferably, the smart card 400 includes an integrated circuit (IC) 410 that includes both the functionality of the smart card 165 and the functionality of the configurable hardware device 60. The smart card 400 may preferably be accessed via the security element reader 135 and the communication bus 110.

The smart card 500 preferably includes an IC 510 and an IC 520. The IC 510 preferably includes the functionality of the smart card 165, and the IC 520 preferably includes the functionality of the configurable hardware device 60. The smart card 500 may preferably be accessed by a smart card reader 530 that is capable of accessing a smart card having two ICs, as described, for example, in the above mentioned U.S. Pat. No. 5,774,546 to Handelman et al, and the communication bus 110.

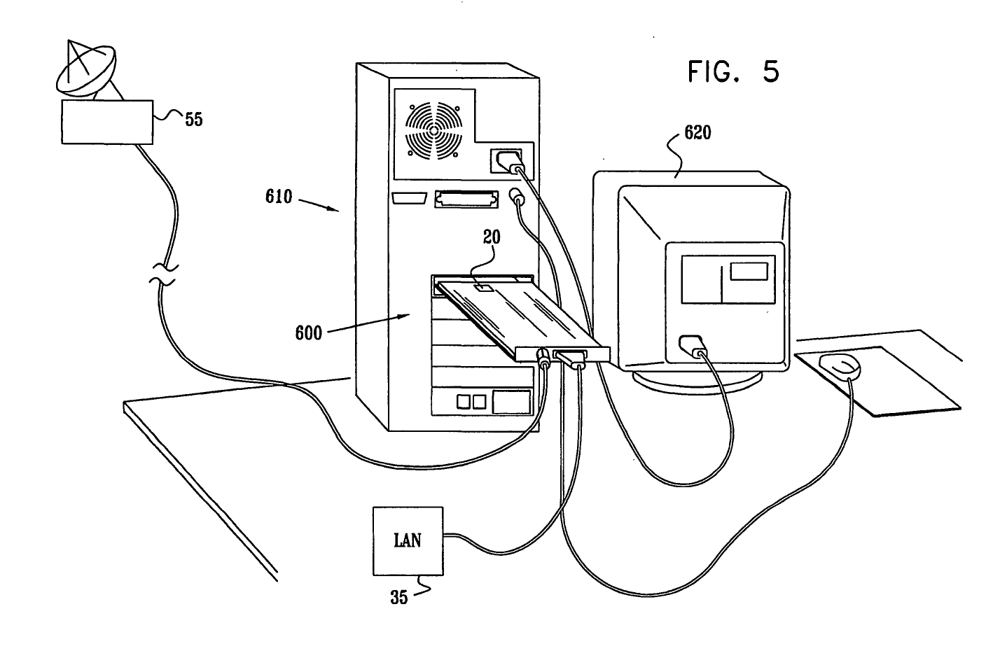

Reference is now additionally made to FIG. 5 which is a simplified partially pictorial, partially block diagram illustration of a preferred implementation of an appliance including the user unit of FIG. 2.

The appliance 600 includes the user unit 20 of FIG. 2.

The appliance 600 shown in FIG. 5 is a plug-in card for a computer 610, but it is appreciated that the user unit 20 may alternatively be embodied in other appliances, such as a cellular telephone, a micro/nano-robotic device and a smart card (all not shown). It is appreciated that in appliances having a limited size, such as the cellular telephone, the micro/nano-robotic device and the smart card, some of the components of the user unit 20, such as the IRD 100, may be either optional or embodied in a separate device (not shown).

Preferably, a monitor 620 of the computer 610 may replace the television 50 and television transmissions may be displayed on the monitor 620 as is well known in the art. It is appreciated that in the above mentioned limited size appliances, the television 50 may be replaced by a built in display, such as a liquid-crystal-display (LCD) (not shown).

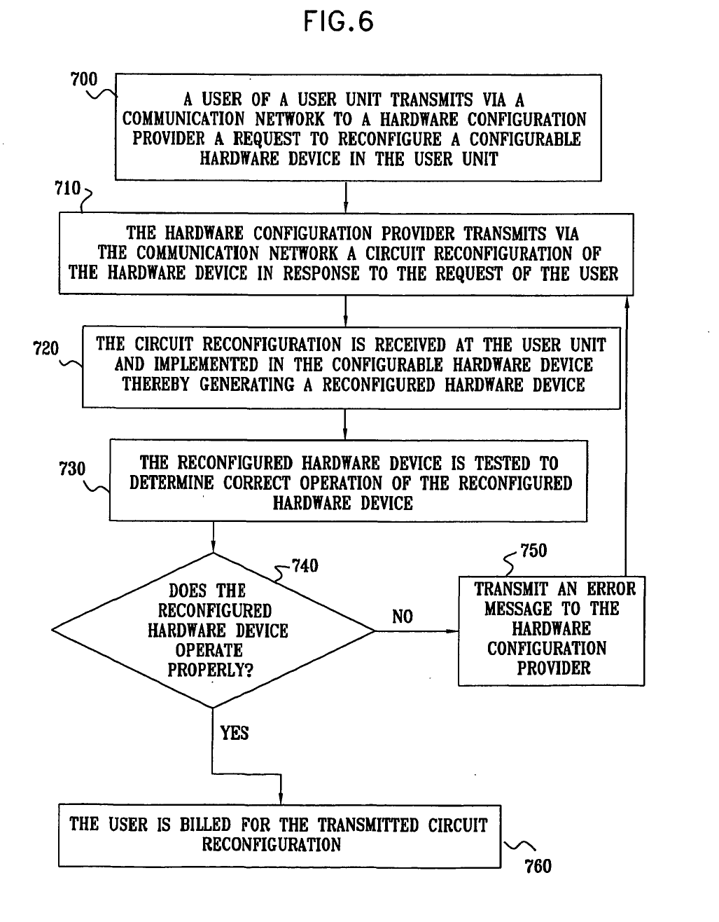

Reference is now made to FIG. 6 which is a simplified flow chart illustration of a preferred method of operation of the apparatus of FIGS. 1 and 2. The method of FIG. 6 preferably includes the following steps:

Preferably, a user of a user unit transmits via a communication network to a hardware configuration provider a request to reconfigure a configurable hardware device in the user unit (step 700). In response to the request of the user, the hardware configuration provider preferably transmits via the communication network a circuit reconfiguration of the configurable hardware device (step 710).

The circuit reconfiguration is preferably received at the user unit and implemented in the configurable hardware device thereby generating a reconfigured hardware device (step 720). Then, the reconfigured hardware device is tested (step 730) to determine correct operation of the reconfigured hardware device (step 740). If the reconfigured hardware device does not operate correctly, an error message is preferably sent to the hardware configuration provider (step 750). In response to receipt of the error message, the hardware configuration provider may, for example, retransmit the circuit reconfiguration.

If the reconfigured hardware device operates correctly, the user may be billed for the transmitted circuit reconfiguration (step 760). Preferably, implementation of the circuit reconfiguration in the configurable hardware device, testing of the reconfigured hardware device, and billing of the user may be performed without user intervention.

It is appreciated that various features of the invention that are, for clarity, described in the contexts of separate embodiments may also be provided in combination in a single embodiment. Conversely, various features of the invention which are, for brevity, described in the context of a single embodiment may also be provided separately or in any suitable subcombination.

It will be appreciated by persons skilled in the art that the present invention is not limited by what has been particularly shown and described hereinabove. Rather the scope of the invention is defined only by the claims which follow:

1-48. (canceled)

49. A method for reconfiguring a complex programmable logic device (CPLD) or a field programmable gate array (FPGA), the method comprising:
receiving at the CPLD/FPGA a circuit reconfiguration of the CPLD/FPGA via a communication network from a hardware configuration provider unit in response to a request from a user of the CPLD/FPGA to reconfigure the CPLD/FPGA;
implementing the circuit reconfiguration of the CPLD/FPGA thereby reconfiguring the CPLD/FPGA and providing a reconfigured CPLD/FPGA;
testing the reconfigured CPLD/FPGA to determine correct operation of the reconfigured CPLD/FPGA;
generating, at the user unit, a message indicating correct operation of the reconfigured CPLD/FPGA in response to the determination of correct operation of the reconfigured CPLD/FPGA; and
transmitting the message from the user unit to the hardware configuration provider unit.

50. The method according to claim 49, wherein the circuit reconfiguration is associated with an application, and the request from the user comprises a payment identification code indicating agreement of the user to pay for the application and for the circuit reconfiguration associated with the application.

51. The method according to claim 49, further comprising enabling use of the circuit reconfiguration in execution of an application in response to billing by the hardware configuration provider unit.

52. The method according to claim 49, wherein the circuit reconfiguration of the CPLD/FPGA is comprised in an applet including an application program and a circuit reconfiguration file, and the implementing includes:
using the circuit reconfiguration file to implement the circuit reconfiguration so as to provide the reconfigured circuit device; and
executing the application program by the reconfigured CPLD/FPGA.

53. The method according to claim 49, wherein the implementing includes:
implementing the circuit reconfiguration of the CPLD/FPGA in the CPLD/FPGA for a predetermined time period; and
deleting the circuit reconfiguration of the CPLD/FPGA from the CPLD/FPGA after the predetermined time period elapses.

54. The method according to claim 53, wherein the deleting step comprises the steps of:
receiving a delete signal from the hardware configuration provider unit by the CPLD/FPGA when the predetermined time period elapses; and
erasing the circuit reconfiguration from the CPLD/FPGA in response to the delete signal.

55. A method for reconfiguring a complex programmable logic device (CPLD) or a field programmable gate array (FPGA), the method comprising:
transmitting via a communication network, from a hardware configuration provider unit to a user unit, a circuit reconfiguration of the CPLD/FPGA in response to a request from a user of the CPLD/FPGA to reconfigure the CPLD/FPGA yielding a reconfigured CPLD/FPGA;
receiving a message generated by the user unit, the message indicating correct operation of the reconfigured CPLD/FPGA; and
billing the user in response to reception of the message at the hardware configuration provider unit.

56. The method according to claim 55, wherein the circuit reconfiguration is associated with an application, and the request from the user comprises a payment identification code indicating agreement of the user to pay for the application and for the circuit reconfiguration associated with the application.

57. The method according to claim 55, further comprising the step of enabling use of the circuit reconfiguration in execution of an application in response to the billing step.

58. The method according to claim 55, wherein the billing step comprises the step of conditionally accessing the circuit reconfiguration to allow use of the circuit reconfiguration in execution of an application.

59. The method according to claim 58, wherein the conditionally accessing step comprises the step of generating an enabling key to allow access to the circuit reconfiguration.

60. The method according to claim 55, wherein the circuit reconfiguration of the CPLD/FPGA comprises a first applet including an application program and a second applet including a circuit reconfiguration file, and the step of transmitting the circuit reconfiguration in response to the request from the user comprises the step of transmitting the first applet and the second applet separately.

61. A user unit, comprising:
a complex programmable logic device (CPLD) or a field programmable gate array (FPGA);
a communication interface unit operatively associated with a communication network and the CPLD/FPGA and operative to receive, from a hardware configuration provider unit via the communication network, a circuit reconfiguration of the CPLD/FPGA in response to a request from a user of the user unit to reconfigure the CPLD/FPGA in the user unit yielding a reconfigured CPLD/FPGA; and
a processor operatively associated with the CPLD/FPGA and the communication interface unit, the processor being operative to test the reconfigured CPLD/FPGA so as to provide a determination of correct operation of the reconfigured CPLD/FPGA for billing of the user.

62. The user unit according to claim 61, wherein the circuit reconfiguration is operative to reconfigure the CPLD/FPGA to include at least one of the following circuit configurations: a digital signal processing (DSP) accelerator; a DES/AES supporter; a camera effects controller; a circuit configuration designed to support an operating system (OS); a graphic accelerator;
and a modular arithmetic accelerator.

63. The user unit according to claim 61, wherein the circuit reconfiguration is implemented for a predetermined time period predetermined by the processor, and the processor is operative to generate a command for deleting the circuit reconfiguration after the predetermined time period elapses.

64. The user unit according to claim 61, wherein the circuit reconfiguration is implemented for a predetermined time period predetermined by the hardware configuration provider unit, and the hardware configuration provider unit is operative to generate a command for deleting the circuit reconfiguration after the predetermined time period elapses.

65. A user unit, comprising:
a complex programmable logic device (CPLD) or a field programmable gate array (FPGA); and
a communication interface unit operatively associated with a first communication network, a second communication network and the CPLD/FPGA, the communication interface unit being operative to receive:
a first portion of a circuit reconfiguration from a first hardware configuration provider unit via the first communication network; and
a second portion of the circuit reconfiguration from a second hardware configuration provider unit via the second communication network,
wherein after implementation of the first portion and the second portion of the circuit reconfiguration in the CPLD/FPGA so as to provide a reconfigured CPLD/FPGA, the reconfigured CPLD/FPGA is operative to execute an application in one of the following: the first communication network; and the second communication network.

66. A user unit, comprising:
a complex programmable logic device (CPLD) or a field programmable gate array (FPGA); and
a communication interface unit operatively associated with a communication network and the CPLD/FPGA and operative to separately receive a first portion of a circuit reconfiguration of the CPLD/FPGA and a second portion of the circuit reconfiguration of the CPLD/FPGA from a hardware configuration provider unit via the communication network, the first portion of the circuit reconfiguration being useful for performing a first set of mathematical computations comprised in a complex mathematical computation, the second portion of the circuit reconfiguration being useful for performing a second set of mathematical computations comprised in the complex mathematical computation,
wherein after implementation of the first portion of the circuit reconfiguration in the CPLD/FPGA, the CPLD/FPGA is enabled to perform the first set of mathematical computations, and
after the implementation of the first portion and after implementation of the second portion of the circuit reconfiguration in the CPLD/FPGA, the CPLD/FPGA is enabled to complete the complex mathematical computation.

67. A method for reconfiguring a complex programmable logic device (CPLD) or a field programmable gate array (FPGA), the method comprising:
receiving, at the CPLD/FPGA, a first portion of a circuit-reconfiguration from a hardware configuration provider unit via a first communication network;
implementing the first portion of the circuit reconfiguration in the CPLD/FPGA thereby providing a partially reconfigured CPLD/FPGA;
receiving, at the CPLD/FPGA, a second portion of the circuit reconfiguration from the hardware configuration provider unit via a second communication network;
implementing the second portion of the circuit reconfiguration in the partially reconfigured CPLD/FPGA thereby providing a reconfigured CPLD/FPGA; and
employing the reconfigured CPLD/FPGA to execute an application in one of the following: the first communication network; and the second communication network.

68. A method for reconfiguring a complex programmable logic device (CPLD) or a field programmable gate array (FPGA) to perform a complex mathematical computation, the method comprising:
receiving a first portion of a circuit reconfiguration via a communication network from a hardware configuration provider unit by the CPLD/FPGA, the first portion of the circuit reconfiguration being useful for performing a first set of mathematical computations from the complex mathematical computation;
implementing the first portion of the circuit reconfiguration in the CPLD/FPGA thereby providing a partially reconfigured CPLD/FPGA;
operating the partially reconfigured CPLD/FPGA to perform the first set of mathematical computations;
receiving a second portion of the circuit reconfiguration via a communication network from the hardware configuration provider unit by the CPLD/FPGA, the second portion of the circuit reconfiguration being useful for performing a second set of mathematical computations from the complex mathematical computation, wherein the complex mathematical computation comprises the first set of mathematical computations and the second set of mathematical computations;
implementing the second portion of the circuit reconfiguration in the CPLD/FPGA thereby providing an entirely reconfigured CPLD/FPGA; and
operating the entirely reconfigured CPLD/FPGA to perform the second set of mathematical computations thereby completing the complex mathematical computation.

69. A user unit, comprising:
a complex programmable logic device (CPLD) or a field programmable gate array (FPGA); and
means for receiving: a first portion of a circuit reconfiguration of the CPLD/FPGA from a first hardware configuration provider unit via a first communication network; and a second portion of the circuit reconfiguration of the CPLD/FPGA from a second hardware configuration provider unit via a second communication network, the entire circuit reconfiguration comprising the second portion of the circuit reconfiguration and the first portion of the circuit reconfiguration,
wherein after implementation of the entire circuit reconfiguration in the CPLD/FPGA so as to provide an entirely reconfigured CPLD/FPGA, the entirely reconfigured CPLD/FPGA is operative to execute an application in one of the following: the first communication network; and the second communication network.

70. A user unit, comprising:
a complex programmable logic device (CPLD) or a field programmable gate array (FPGA); and
means for receiving a first portion of a circuit reconfiguration of the CPLD/FPGA and a second portion of the circuit reconfiguration of the CPLD/FPGA from a hardware configuration provider unit via a communication network, the first portion of the circuit reconfiguration being useful for performing a first set of mathematical computations comprised in a complex mathematical computation, the second portion of the circuit reconfiguration being useful for performing a second set of mathematical computations comprised in the complex mathematical computation,
wherein after implementation of the first portion of the circuit reconfiguration in the CPLD/FPGA, the CPLD/FPGA is enabled to perform the first set of mathematical computations, and
after the implementation of the first portion and after implementation of the second portion of the circuit reconfiguration in the CPLD/FPGA, the CPLD/FPGA is enabled to complete the complex mathematical computation.
